(19) United States
(12) Patent Application Publication
(10) Pub. No.: US 2026/0165057 A1
(43) Pub. Date: Jun. 11, 2026

(54) SUBSTRATE PROCESSING APPARATUS AND SUBSTRATE PROCESSING METHOD

(71) Applicant: SEMES CO., LTD., Cheonan-si (KR)

(72) Inventors: Yong Jun KIM, Suwon-si (KR); Tae Keun KIM, Siheung-si (KR); Kang Sul KIM, Hwaseong-si (KR); Jun Hee CHOI, Yongin-si (KR); Kyeong Min LEE, Hwaseong-si (KR)

(73) Assignee: SEMES CO., LTD., Cheonan-si (KR)

(21) Appl. No.: 19/409,951

(22) Filed: Dec. 5, 2025

(30) Foreign Application Priority Data
Dec. 9, 2024 (KR) 10-2024-0181816

(51) Int. Cl. H01L 21/306; H01L 21/67; H01L 21/687

(52) U.S. Cl. CPC H10P 50/642; H10P 72/0424; H10P 72/0602; H10P 72/7618

(57) ABSTRACT

Disclosed is a method of processing a substrate. The method includes: an etchant supply operation of rotating a substrate on which a first film and a second film are formed and supplying an etchant for etching the first film onto the substrate; and a puddle operation of stopping the supply of the etchant, forming a puddle made of the etchant on the substrate, and selectively etching the first film with respect to the second film by the puddle, in which the puddle is a liquid film made of the etchant, and a temperature of the puddle is adjusted in the puddle operation.

### CROSS-REFERENCE TO RELATED APPLICATION

This application claims priority to and the benefit of Korean Patent Application No. 10-2024-0181816 filed in the Korean Intellectual Property Office on Dec. 9, 2024, the entire contents of which are incorporated herein by reference.

### TECHNICAL FIELD

The present invention relates to a substrate processing apparatus and a substrate processing method, and more particularly, to a substrate processing apparatus and a substrate processing method of processing a substrate by adjusting a temperature of a puddle.

### BACKGROUND ART

The semiconductor process includes a wet process of supplying a treatment liquid onto a substrate so that a substrate and the treatment liquid react physically and chemically. This process is performed by placing the substrate on a spin chuck so that a pattern surface faces up or down, supplying the treatment liquid onto the substrate in a state in which the spin chuck is rotated, and then drying a wafer.

During the wet process, the treatment liquid is supplied at a constant temperature. In addition, since the substrate rotates at a high speed, the treatment liquid is continuously supplied until the process is completed. At this time, a problem arises that it is difficult to adjust the temperature of the treatment liquid. In particular, when the treatment liquid is an etchant, since the etch rate and the selectivity are greatly affected by the temperature of the etchant, the etching process is bound to proceed at a fixed etch rate and selectivity.

However, as the etching process proceeds, the required etch rate and selectivity may change. For example, a relatively high etch rate is required in the initial stage of etching, but a high selectivity may be required in the later stage of etching. However, as mentioned above, since it is difficult to adjust the temperature of the etchant, it is difficult to appropriately control the etch rate and selectivity by adjusting the temperature of the etchant according to the process.

### SUMMARY OF THE INVENTION

The present invention has been made in an effort to provide a substrate processing apparatus and a substrate processing method capable of adjusting a temperature of a puddle formed on a substrate.

The present invention has also been made in an effort to provide a substrate processing apparatus and a substrate processing method capable of adjusting an etch rate and a selectivity during an etching process.

The present invention has also been made in an effort to provide a substrate processing apparatus and a substrate processing method capable of reducing the consumption of a treatment liquid.

The objectives of the present disclosure are not limited thereto and other objectives not stated herein may be clearly understood by those skilled in the art from the following description.

An exemplary embodiment of the present disclosure, a method of processing a substrate, the method comprising: an etchant supply operation of rotating a substrate on which a first film and a second film are formed and supplying an etchant for etching the first film onto the substrate; and a puddle operation of stopping the supply of the etchant, forming a puddle made of the etchant on the substrate, and selectively etching the first film with respect to the second film by the puddle, wherein the puddle is a liquid film made of the etchant, and a temperature of the puddle may be adjusted in the puddle operation.

According to the exemplary embodiment of the present invention, wherein the etchant may be supplied in a heated state.

According to the exemplary embodiment of the present invention, wherein the temperature of the puddle is adjusted from a first temperature to a second temperature, and the second temperature may be lower than the first temperature.

According to the exemplary embodiment of the present invention, wherein the first temperature is higher than room temperature, and the second temperature may be lower than room temperature.

According to the exemplary embodiment of the present invention, wherein the etchant may be supplied in a heated state.

According to the exemplary embodiment of the present invention, wherein a rotation speed of the substrate in the puddle operation may be lower than a rotation speed of the substrate in the etchant supply operation.

According to the exemplary embodiment of the present invention, wherein the temperature of the puddle may be adjusted by supplying a temperature adjustment fluid to a rear surface of the substrate.

According to the exemplary embodiment of the present invention, wherein during the etchant supply operation and the puddle operation, descending airflow is provided to a space where the substrate is located, and in the puddle operation, the adjustment of the temperature of the puddle may be performed by the descending airflow.

According to the exemplary embodiment of the present invention, wherein a temperature of the descending airflow in the etchant supply operation is a first temperature, a temperature of the descending airflow in the puddle operation is a second temperature, and the second temperature may be lower than the first temperature.

According to the exemplary embodiment of the present invention, wherein the first film and the second film may be alternately stacked multiple times.

According to the exemplary embodiment of the present invention, wherein the first film contains silicon germanium (SiGe), and the second film may contains silicon (Si).

An exemplary embodiment of the present disclosure, an apparatus for processing a substrate, the apparatus comprising: a housing providing an inner space; a cup body disposed in the inner space and providing a treatment space for processing the substrate; a support unit for supporting and rotating a substrate on which a first film and a second film are formed in the treatment space; an etchant supply unit for supplying an etchant onto a substrate supported by the support unit; a fan unit for providing descending airflow to the treatment space; a temperature adjusting unit for adjusting a temperature of a puddle formed on the substrate supported on the support unit; and a controller, wherein the controller controls the support unit, the etchant supply unit, and the temperature adjusting unit to sequentially perform: an etchant supply operation of rotating a substrate on which the first film and the second film are formed and supplying an etchant for etching the first film onto the substrate; and a puddle operation of stopping the supply of the etchant, forming a puddle made of the etchant on the substrate, and selectively etching the first film with respect to the second film by the puddle.

According to the exemplary embodiment of the present invention, wherein the temperature adjusting unit may includes: a rear nozzle for discharging a temperature adjustment medium to a rear surface of the substrate; and a temperature adjuster for adjusting a temperature of the temperature adjustment medium.

According to the exemplary embodiment of the present invention, wherein the temperature adjustment medium may be nitrogen, inert gas, or deionized water.

According to the exemplary embodiment of the present invention, wherein the temperature adjusting unit may includes a temperature adjuster for adjusting a temperature of the descending airflow.

According to the exemplary embodiment of the present invention, wherein the etchant supply unit includes a heater that heats the etchant, and in the etchant supply operation, the etchant is heated to the first temperature and supplied, in the temperature adjustment operation, a temperature of the puddle is adjusted to the second temperature, and the second temperature may be lower than the first temperature.

According to the exemplary embodiment of the present invention, wherein the first film and the second film are alternately stacked multiple times, the first film contains silicon germanium (SiGe), and the second film may contains silicon (Si).

An exemplary embodiment of the present disclosure, a method of processing a substrate, the method comprising: an etchant supply operation of rotating a substrate on which a first film and a second film are formed and supplying an etchant for etching the first film onto the substrate; and a puddle operation of stopping the supply of the etchant, forming a puddle made of the etchant on the substrate, and selectively etching the first film with respect to the second film by the puddle, wherein a rotation speed of the substrate in the puddle operation is lower than a rotation speed of the substrate in the etchant supply operation, the puddle is a liquid film made of the etchant, the etchant is supplied in a heated state, a temperature of the puddle is adjusted from a first temperature to a second temperature, the first temperature is higher than room temperature, the second temperature is lower than room temperature, the first film may contains silicon germanium (SiGe), and the second film contains silicon (Si).

According to the exemplary embodiment of the present invention, wherein the temperature of the puddle may be adjusted by supplying a temperature adjustment fluid to a rear surface of the substrate.

According to the exemplary embodiment of the present invention, wherein during the etchant supply operation and the puddle operation, descending airflow is provided to a space where the substrate is located, and in the puddle operation, the adjustment of the temperature of the puddle may be performed by the descending airflow.

According to the exemplary embodiment of the present invention, it is possible to adjust a temperature of a puddle formed on a substrate.

Further, according to the exemplary embodiment of the present invention, it is possible to adjust an etch rate and a selectivity during an etching process.

According to the exemplary embodiment of the present invention, it is possible to reduce the consumption of a treatment liquid.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a top plan view schematically illustrating a substrate processing apparatus according to an exemplary embodiment of the present invention.

FIG. 2 is a diagram schematically illustrating a state of a substrate to be processed according to an exemplary embodiment of the present invention.

FIG. 3 is a diagram schematically illustrating an exemplary embodiment of a liquid treating chamber of FIG. 1.

FIG. 4 is a diagram schematically illustrating another exemplary embodiment of the liquid treating chamber of FIG. 1.

FIG. 5 is a flowchart illustrating a substrate processing method according to an exemplary embodiment of the present invention.

FIG. 6 is a diagram schematically illustrating an exemplary embodiment of a puddle operation of FIG. 5.

FIG. 7 is a diagram schematically illustrating another exemplary embodiment of the puddle operation of FIG. 5.

FIG. 8 is a diagram illustrating the states before and after a first film and a second film formed on the substrate are etched with an etchant.

FIG. 9 is a diagram schematically illustrating another exemplary embodiment of the liquid treating chamber of FIG. 3.

FIG. 10 is a diagram schematically illustrating another exemplary embodiment of the liquid treating chamber of FIG. 3.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be treated. However, the technical idea of the present invention may be applied to devices used for treating other types of substrates other than wafers as objects to be treated.

Hereinafter, an exemplary embodiment of the present invention will be described with reference to the accompanying drawings.

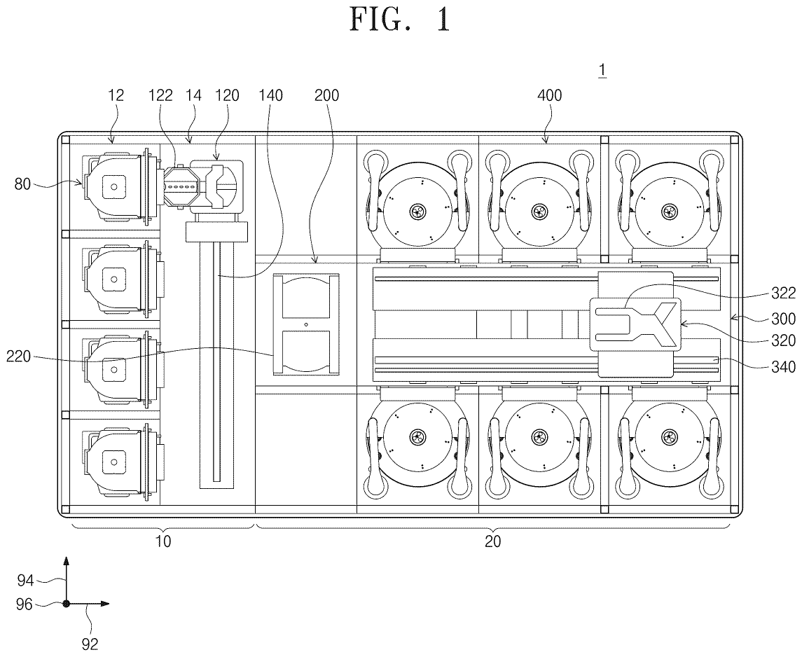

FIG. 1 is a top plan view schematically illustrating a substrate processing apparatus according to an exemplary embodiment of the present invention. Referring to FIG. 1, a substrate processing apparatus includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 92, and when viewed from above, a direction perpendicular to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80.

A longitudinal direction of the index module 10 is provided in the second direction 94. The index module 10 includes a load port 12 and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal direction is the second direction 94 is provided within the index frame 14, and the index robot 120 may be provided to be movable on the guide rail 140. The index robot 120 includes a hand 122 on which the substrate W is placed, and the hand 122 may be provided to be movable forward and backward, rotatable about the third direction 96, and movable along the third direction 96. A plurality of hands 122 are provided to be spaced apart in the vertical direction, and the hands 122 may move forward and backward independently of each other.

The treating module 20 includes a buffer unit 200, a transfer chamber 300, and a treating chamber 400. The buffer unit 200 provides a space in which the substrate W loaded into the treating module 20 and the substrate W unloaded from the treating module 20 stay temporarily. The treating chamber 400 performs a processing process of liquid-treating the substrate W by supplying a liquid onto the substrate W. The transfer chamber 300 transfers the substrate W between the buffer unit 200 and the liquid treating chamber 400.

The transfer chamber 300 may be provided so that a longitudinal direction is the first direction 92. The buffer unit 200 may be disposed between the index module 10 and the transfer chamber 300. A plurality of liquid treating chambers 400 is provided and may be disposed on the side of the transfer chamber 300. The liquid treating chamber 400 and the transfer chamber 300 may be disposed in the second direction 94. The buffer unit 200 may be located at one end of the transfer chamber 300.

According to the example, the liquid treating chambers 400 are respectively disposed on opposite sides of the transfer chamber 300. At each of opposite sides of the transfer chamber 300, the liquid treating chambers 400 may be provided in an array of A×B (each of A and B is 1 or a natural number greater than 1) in the first direction 92 and the third direction 96.

The transfer chamber 300 includes a transfer robot 320. A guide rail 340 having a longitudinal direction in the first direction 92 is provided in the transfer chamber 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

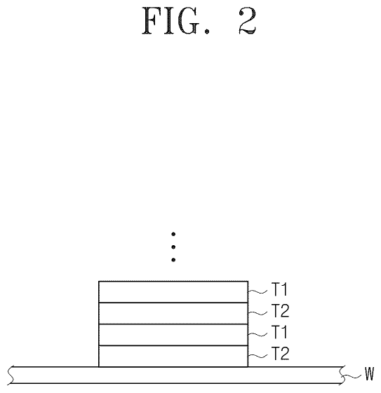

FIG. 2 is a diagram schematically illustrating a state of a substrate to be processed according to an exemplary embodiment of the present invention. Referring to FIG. 2, the substrate W to be processed is the substrate W on which a first film T1 and a second film T2 are formed, and the first film T1 and the second film T2 may be alternately stacked. The first film T1 may be a film including silicon germanium (SiGe), and the second film may be a film including silicon (Si). The thickness of the first film T1 may be twice the thickness of the second film T1. However, the present invention is not limited thereto.

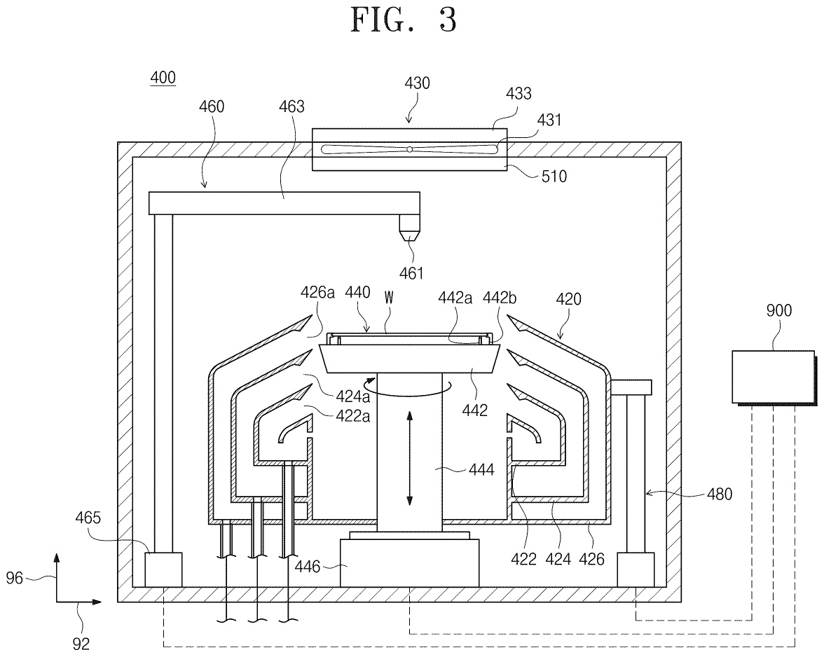

FIG. 3 is a diagram schematically illustrating an exemplary embodiment of the liquid treating chamber 400 of FIG. 1. Referring to FIG. 3, the liquid treating chamber 400 has a housing 410, a cup 420, a fan filter unit 430, a support unit 440, an etchant supply unit 460, a lifting unit 480, a temperature adjusting unit 500, and a controller 900.

The housing 410 is provided in a generally rectangular parallelepiped shape. The cup 420, the support unit 440, and the etchant supply unit 460 are disposed within the housing 410.

The cup 420 has a treatment space with an open top, and the substrate W is liquid-treated in the treatment space. The support unit 440 supports the substrate W in the treatment space. The etchant supply unit 460 supplies the liquid to the substrate W supported by the support unit 440. The liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treating process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The fan filter unit 430 may include a fan 431 and a filter 433. The fan filter unit 430 may be provided on the upper wall of the housing 410. Accordingly, the fan filter unit 430 may supply the descending airflow G into the housing 410. The descending airflow G may flow onto the substrate W supported by the support unit 440. Accordingly, the descending airflow G may contact the puddle P formed on the substrate W and adjust the temperature of the puddle P.

The support unit 440 includes a spin chuck 442 and a drive shaft 444. An upper surface of the spin chuck 442 is provided in a generally circular shape and may have a larger diameter than the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge of the spin chuck 442. The chuck pin 442b is provided to protrude upward from the support plate 442, and supports a side portion of the substrate W so that the substrate W is not separated from the support unit 440 when the substrate W is rotated. The drive shaft 444 is driven by the driver 446, is connected to the center of the rear surface of the substrate W, and rotates the spin chuck 442 about its central axis.

The etchant supply unit 460 supplies the etchant onto the substrate W supported by the support unit 440. The etchant is a kind of treatment liquid for processing the substrate W, and hereinafter, the present invention will be described based on the case where the substrate is processed by supplying the etchant as an example. The etchant supply unit 460 has a first nozzle 461, an arm 463, and a driver 465. The first nozzle 461 is connected with an etchant supply source (not illustrated). The first nozzle 461 and the etchant supply source may be connected with an etchant supply line (not illustrated). Thus, the first nozzle 461 may supply the etchant onto the substrate W. The driver 465 moves a position of the first nozzle 461. The first nozzle 461 is supported by the arm 463, and the arm 463 may be driven by the driver 465. Thus, a position of the nozzle 461 may be changed. Also, the etchant supply unit 460 may include a heater (not illustrated). The heater may heat an etchant. The heater may be installed on an etchant supply source and/or in an etchant supply line. The heater is sufficient as long as it is a known means for heating a liquid that processes a substrate. According to an example, the etchant may be heated to a first temperature by the heater, and the first temperature may be higher than room temperature.

The etchant supply unit 460 may optionally further include one or a plurality of nozzles in addition to the first nozzle 461. The added nozzle may supply another type of treatment liquid to the substrate. For example, the different types of treatment liquid may be a drying solution for drying the substrate W. For example, the drying solution may be isopropyl alcohol.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 480 may move the support unit 440 in the vertical direction.

The temperature adjusting unit 500 controls the temperature of a puddle P formed on the substrate W. The temperature adjusting unit 500 may include a temperature adjuster 510. The temperature adjuster 510 is provided to adjust the temperature of the descending airflow G passing through the temperature adjuster 510. The temperature adjuster 510 may be installed under the fan filter unit 430. According to one example, the temperature adjuster 510 may include a heater or a chiller. The temperature adjuster 510 may set the temperature of the descending airflow G to a second temperature. The second temperature may be a temperature lower than room temperature. Accordingly, the descending airflow G may contact the puddle P so that the temperature of the puddle P becomes the second temperature.

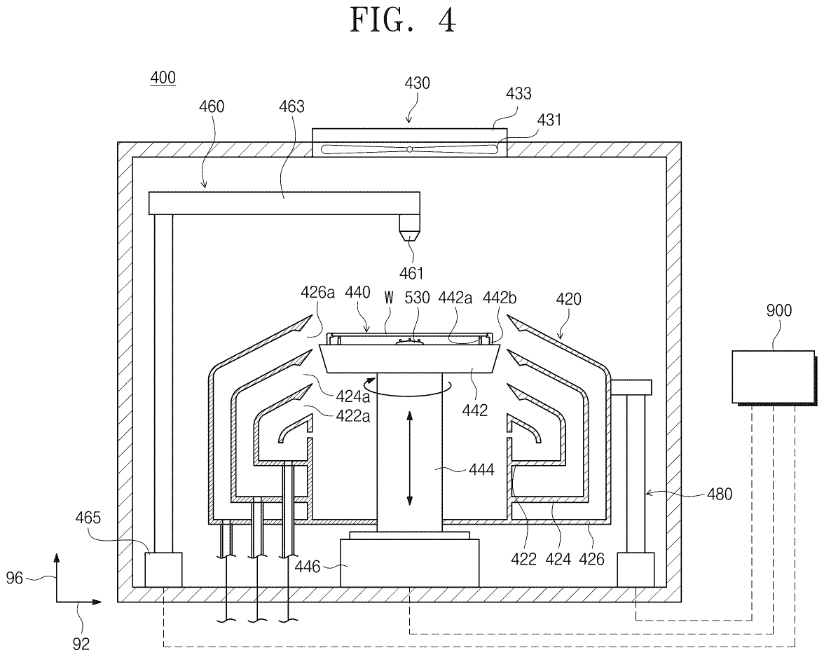

FIG. 4 is a diagram schematically illustrating another exemplary embodiment of the liquid treating chamber of FIG. 1. Referring to FIG. 4, the temperature adjusting unit 500 may include a rear nozzle 530. The rear nozzle 530 is provided to inject a temperature adjustment medium toward the rear surface of the substrate W. The rear nozzle 530 may discharge the temperature adjustment medium toward the center of the rear surface of the substrate W. The temperature adjustment medium may be liquid or gas. Also, the temperature adjustment medium may be provided at the second temperature. According to an example, the temperature adjustment medium may be inert gas, nitrogen gas, or Deionized Water (DIW), and the second temperature may be a temperature lower than the first temperature. A through hole in which the rear nozzle 446 is installed is formed at the center of the spin chuck 453, and the rear nozzle 530 may be installed on the upper surface of the spin chuck 442 along the through hole.

Each of the configurations of the substrate processing apparatus described above may be controlled by the controller 900. The controller 900 may include a process controller formed of a microprocessor (computer) that executes the control of the substrate processing apparatus, a user interface formed of a keyboard in which an operator performs a command input operation or the like in order to manage the substrate processing apparatus, a display for visualizing and displaying an operation situation of the substrate processing apparatus, and the like, and a storage unit storing a control program for executing the process executed in the substrate processing apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

Hereinafter, a method of processing a substrate will be described. The substrate processing method described below may be performed by the substrate processing apparatus described with reference to FIGS. 1 to 4. Accordingly, hereinafter, a substrate processing method according to an exemplary embodiment will be described by referring to reference numerals illustrated in FIGS. 1 to 4. In addition, the substrate processing method described below may be performed by controlling, by the controller 900, components included in the substrate processing apparatus described above.

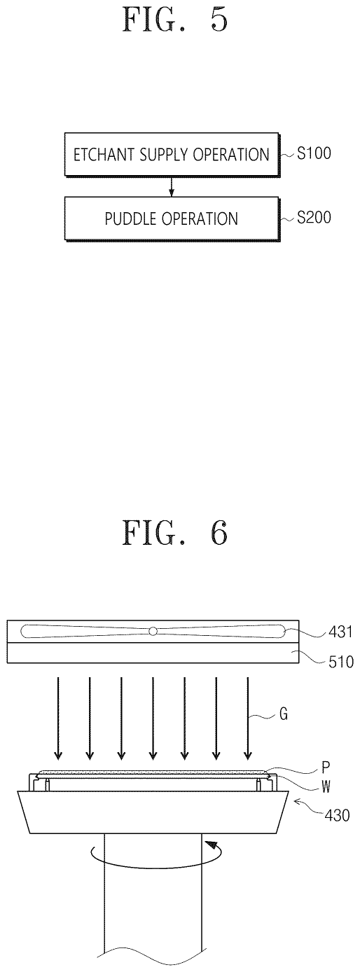

FIG. 5 is a flowchart illustrating a substrate processing method according to an exemplary embodiment of the present invention. Referring to FIG. 5, the substrate processing method may include an etchant supplying operation S100 and a puddle operation S200.

The etchant supplying operation S100 is an operation of supplying an etchant onto the substrate W. The substrate W is loaded into the support unit 440 and is supported by the chuck pin 442b. Thereafter, when the spin chuck 442 is rotated, the etchant is discharged from the first nozzle 461 to the substrate W. The etchant may be in a state of being heated by the heater. The temperature of the etchant may be a first temperature. The first temperature may be higher than room temperature. The discharged etchant is diffused in the substrate W to form a liquid film covering the entire surface of the substrate W.

After the etchant supply operation S100, a puddle operation S200 is performed. When the etchant supply operation S100 is completed, the supply of the etchant is stopped. The spin chuck 442 rotates at a low speed to prevent separation of the liquid film formed in the etchant supply operation S100. The rotation speed of the substrate W in the puddle operation S200 may be lower than the rotation speed of the substrate W in the etchant supply operation S100. According to an example, the spin chuck 442 may be rotated at a speed of 50 RPM or less to form the puddle P. Accordingly, the puddle P may be formed on the substrate W. The puddle P may react with the film formed on the substrate W while being on the substrate W. The film formed on the substrate W may be the first film T1 and the second film T2. Also, the first film T1 and the second film T2 may be repeatedly stacked. According to an example, the etchant may selectively etch the first film T1 with respect to the second film T2, the first film T1 may be a silicon germanium (SiGe) film, and the second film may be a silicon (Si) film.

In addition, the temperature of the puddle P may be adjusted in the puddle operation S200. The temperature of the puddle P may be adjusted from the first temperature to the second temperature, and the second temperature may be lower than the first temperature. According to an example, the second temperature may be a temperature lower than room temperature. The temperature adjustment may be performed immediately after the puddle P is formed, or may be performed after a certain period of time has elapsed after the puddle P is formed.

FIG. 6 is a diagram illustrating a state in which the temperature of a puddle is adjusted using the temperature adjuster 510 in the puddle operation of FIG. 5. Referring to FIG. 6, the temperature adjuster 510 adjusts the temperature of the descending airflow G. The descending airflow G may be adjusted to the second temperature. The descending airflow G having the second temperature flows around the substrate W and the puddle P formed on the substrate W. The descending airflow G is in contact with the puddle P, and the temperature of the puddle P may be adjusted to the second temperature.

FIG. 7 is a diagram illustrating a state in which the temperature of a puddle is adjusted using the rear nozzle. Referring to FIG. 7, the rear nozzle 530 discharges the temperature adjustment medium M to the rear surface of the substrate W. The temperature adjustment medium M may be provided as inert gas, nitrogen gas, or deionized water having low reactivity. Also, the temperature adjustment medium M may have the second temperature. Accordingly, the temperature of the substrate W is adjusted to the second temperature, and the temperature of the puddle P is gradually lowered from the first temperature to the second temperature.

In general, during a wet process, the temperature of the treatment liquid affects the processing speed. When the treatment liquid is provided as an etchant, the temperature of the etchant affects not only the etch rate but also the selectivity. As the temperature of the etchant is higher, the etch rate is more improved, but the selectivity decreases, and as the temperature of the etchant is lower, the selectivity is more improved, but the etch rate decreases.

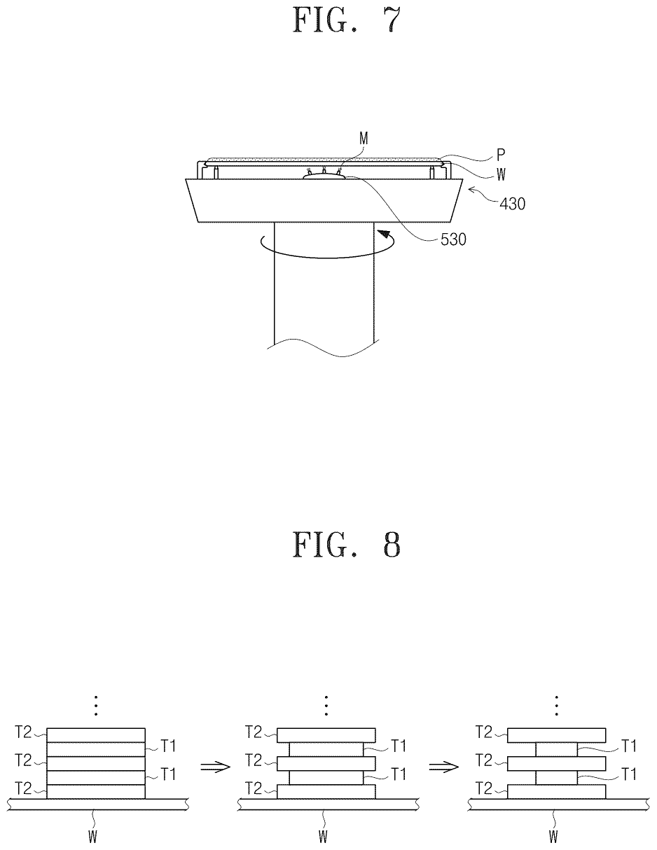

FIG. 8 is a diagram sequentially illustrating a substrate processed by the substrate processing method according to the exemplary embodiment of the present invention. Hereinafter, the present invention will be described based on the case where the first film T1 is etch treated with the etchant will be described as an example with reference to FIG. 8. Referring to FIG. 8, in the initial etching process, the difference in the areas in which the first film T1 and the second film T2 are exposed to the etchant is not large. In this case, it is important to reduce the processing time by increasing the etch rate by supplying the etchant at a high temperature. However, as the etching process gradually proceeds, the ratio in which the second film T2 is exposed to the etchant increases. Since the possibility of etching the second film T2 increases as the area in which the second film T2 is exposed to the etchant increases, the selectivity needs to be improved to selectively etch only the first film T1. In this case, it is important to accurately etch the etchant by gradually reducing the temperature of the etchant and increasing the selectivity. According to the exemplary embodiment of the present invention, by supplying the etchant at the first temperature at the time of supplying the etchant, forming the puddle P and lowering the temperature of the puddles P to the second temperature, a high etch rate may be secured in the initial etching process, and a high selectivity may be secured as the etching process proceeds. Accordingly, it is possible to shorten the time required for the etching process and achieve the accuracy of the etching. In addition, by forming and treating the puddle P, it is possible to reduce the consumption of the etchant.

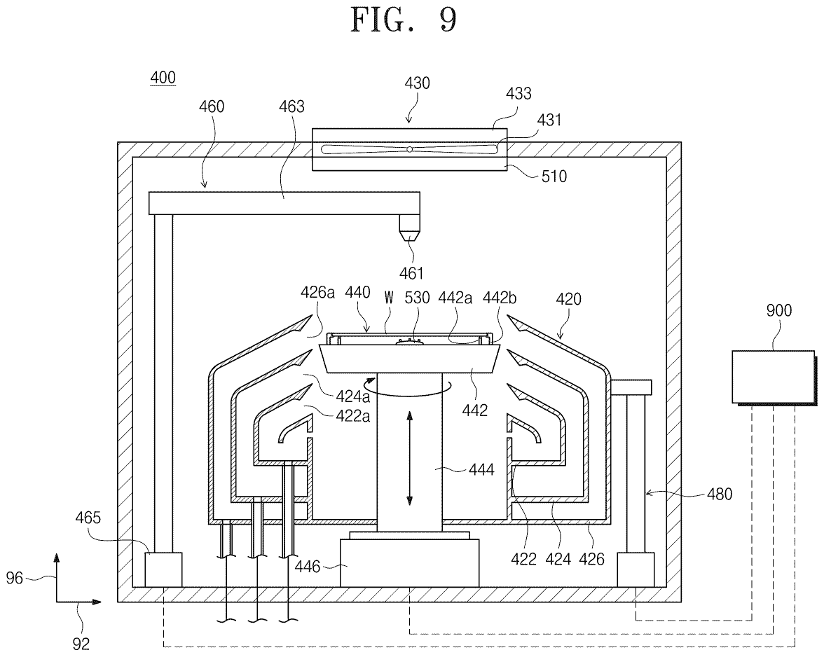

In the above-described example, the present invention has been described based on the case where the temperature adjusting unit 500 includes the temperature adjuster 510 or the rear nozzle 530. However, the present invention is not limited thereto, and may include both the temperature adjuster 510 and the rear nozzle 530 as illustrated in FIG. 9.

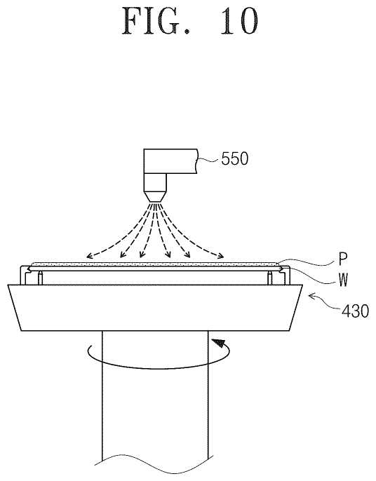

In addition, in the above-described example, the present invention has been described based on the case where temperature adjuster 510 is provided as an example. However, the present invention is not limited thereto, and an upper nozzle 550 may be further provided as illustrated in FIG. 10. Also, the temperature adjuster 510 and the upper nozzle 550 may be provided together, or only the upper nozzle 550 may be provided. The upper nozzle 550 is provided to inject the temperature adjustment medium toward the puddle P formed on the substrate W. The upper nozzle 550 may discharge the temperature adjustment medium onto the substrate W supported by the support unit 440. The temperature adjustment medium may be gas, and the gas may have the second temperature. According to an example, the second temperature may be a temperature lower than the first temperature and lower than room temperature. Also, the gas may be inert gas or nitrogen gas. The temperature of the puddle P may be adjusted to the second temperature by injecting gas from the upper nozzle 550 into the puddle P formed on the substrate W. Also, the upper nozzle 550 and the first nozzle 462 are supported by the different arms 461, respectively, and the arms 461 may move independently. Alternatively, the first nozzle 461 and the upper nozzle 550 may be mounted on the same arm and moved simultaneously.

In addition, in the above-described example, the present invention has been described based on the case where the etchant is presented as a means for processing a substrate, and an etching characteristic is changed according to a temperature change of the puddle P composed of the etchant as an example. However, the present invention is not limited thereto, and various types of treatment liquids for processing a substrate instead of the etchant may be provided. In this case, when the processing characteristics are changed (e.g., formation of bubbles in the treatment liquid, thermal stress applied to the substrate, or evaporation reduction of the treatment liquid) according to the temperature change of the treatment liquid, it is a matter of course that the substrate processing method of the present invention may be applied and implemented.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1. A method of processing a substrate, the method comprising:
an etchant supply operation of rotating a substrate on which a first film and a second film are formed and supplying an etchant for etching the first film onto the substrate; and
a puddle operation of stopping the supply of the etchant, forming a puddle made of the etchant on the substrate, and selectively etching the first film with respect to the second film by the puddle,
wherein the puddle is a liquid film made of the etchant, and
a temperature of the puddle is adjusted in the puddle operation.

2. The method of claim 1, wherein the etchant is supplied in a heated state.

3. The method of claim 2, wherein the temperature of the puddle is adjusted from a first temperature to a second temperature, and
the second temperature is lower than the first temperature.

4. The method of claim 3, wherein the first temperature is higher than room temperature, and
the second temperature is lower than room temperature.

5. The method of claim 1, wherein the etchant is supplied in a heated state.

6. The method of claim 1, wherein a rotation speed of the substrate in the puddle operation is lower than a rotation speed of the substrate in the etchant supply operation.

7. The method of claim 1, wherein the temperature of the puddle is adjusted by supplying a temperature adjustment fluid to a rear surface of the substrate.

8. The method of claim 1, wherein during the etchant supply operation and the puddle operation, descending airflow is provided to a space where the substrate is located, and
in the puddle operation, the adjustment of the temperature of the puddle is performed by the descending airflow.

9. The method of claim 8, wherein a temperature of the descending airflow in the etchant supply operation is a first temperature,
a temperature of the descending airflow in the puddle operation is a second temperature, and
the second temperature is lower than the first temperature.

10. The method of claim 1, wherein the first film and the second film are alternately stacked multiple times.

11. The method of claim 10, wherein the first film contains silicon germanium (SiGe), and
the second film contains silicon (Si).

12-17. (canceled)

18. A method of processing a substrate, the method comprising:
an etchant supply operation of rotating a substrate on which a first film and a second film are formed and supplying an etchant for etching the first film onto the substrate; and
a puddle operation of stopping the supply of the etchant, forming a puddle made of the etchant on the substrate, and selectively etching the first film with respect to the second film by the puddle,
wherein a rotation speed of the substrate in the puddle operation is lower than a rotation speed of the substrate in the etchant supply operation,
the puddle is a liquid film made of the etchant,
the etchant is supplied in a heated state,
a temperature of the puddle is adjusted from a first temperature to a second temperature,
the first temperature is higher than room temperature,
the second temperature is lower than room temperature,
the first film contains silicon germanium (SiGe), and
the second film contains silicon (Si).

19. The method of claim 18, wherein the temperature of the puddle is adjusted by supplying a temperature adjustment fluid to a rear surface of the substrate.

20. The method of claim 18, wherein during the etchant supply operation and the puddle operation, descending airflow is provided to a space where the substrate is located, and
in the puddle operation, the adjustment of the temperature of the puddle is performed by the descending airflow.
